(19) United States
(12) Patent Application Publication
(10) Pub. No.: US 2026/0268055 A1
(43) Pub. Date: Sep. 10, 2026

(54) COMPRESSED SCAN COLLAR ARCHITECTURE FOR ASYNCHRONOUS FINITE STATE MACHINES

(71) Applicant: STMicroelectronics International N.V., Geneva (CH)

(72) Inventors: Claudio Mucci, Bologna (IT); Matilde Semilia, Ferrara (IT)

(21) Appl. No.: 19/075,345

(22) Filed: Mar. 10, 2025

(51) Int. Cl. G06F 30/333

(52) U.S. Cl. CPC G06F 30/333

(57) ABSTRACT

According to an embodiment, a compressed scan collar architecture for testing asynchronous finite state machines (AFSMs) reduces test infrastructure overhead while maintaining fault coverage. The architecture includes a compressed input circuit with shared input test registers allocated to compatible functional signals based on source and destination state relationships. Functional signals can share an input test register when their corresponding state transitions have different source states and destination states are not source states of other transitions. The architecture also includes a compressed output circuit with shared output test registers allocated to compatible state signals based on state transition relationships. States can share an output test register when no direct transition exists between them. The number of input test registers corresponds to the maximum state fanout plus one, while state signals from compatible states are combined using logic gates for observation.

### TECHNICAL FIELD

The present disclosure generally relates to design for testability (DFT) and, in particular embodiments, to a compressed scan collar architecture for asynchronous finite state machines.

### BACKGROUND

Asynchronous Finite State Machines (AFSMs) can provide control logic capabilities without relying on clock signals in digital circuit design. Traditional synchronous Finite State Machines (FSMs) utilize clock signals to coordinate state transitions, which can limit their reaction time to input changes based on the clock frequency. Increasing clock frequency to improve reaction time can lead to proportionally higher dynamic power consumption.

AFSMs implement control logic by replacing clock-based synchronization with handshake protocols between components. Removing clock signals allows AFSMs to react to input changes at the minimum possible time for a given technology while maintaining low power consumption. These characteristics make AFSMs suitable for control-driven systems requiring high-speed responses and ultra-low power consumption, such as high-performance DC-DC converters.

Since AFSMs operate without clock synchronization, they can be susceptible to glitches in the input signals. To preserve correct behavior and avoid false transitions, state encoding in AFSMs typically utilizes one-hot encoding (also known as 1/N code), where each state corresponds to a single active bit. Further, the combinational logic in AFSMs can be designed to minimize glitch propagation through redundant logic structures.

Testing synchronous circuits typically leverages the existing sequential elements (e.g., flip-flops) by configuring them into scan chains during test mode. However, testing asynchronous circuits can present challenges since they lack the regular clock-based structure of synchronous designs. The testing approach for AFSMs should account for their clockless nature while enabling thorough verification of state transitions and fault detection.

### SUMMARY

Technical advantages are generally achieved by embodiments of this disclosure, which describe a compressed scan collar architecture for asynchronous finite state machines.

A first aspect relates to a method of implementing a scan collar architecture for testing an asynchronous finite state machine (AFSM), the method comprising receiving a plurality of functional signals corresponding to state transitions in the AFSM; determining compatibility between the functional signals based on source states and destination states of the state transitions; allocating compatible functional signals to shared input test registers of the scan collar architecture, wherein functional signals are compatible in response to their corresponding state transitions having different source states and in response to a destination state of one state transition not being a source state of another state transition; and providing test input signals to the AFSM through the shared input test registers.

A second aspect relates to a method of implementing a scan collar architecture for testing an asynchronous finite state machine (AFSM), the method comprising identifying states of the AFSM; generating an evolution matrix representing relationships between the states and state transition arcs of the AFSM; determining compatibility between states based on the evolution matrix, wherein states are compatible in response to having no direct transition relationship between them; allocating compatible states to shared output test registers of the scan collar architecture; and monitoring state transitions through the shared output test registers.

A third aspect relates to design for test (DFT) architecture for an asynchronous finite state machine (AFSM), comprising a compressed input circuit including a plurality of shared input test registers; a plurality of multiplexers coupled to the shared input test registers; and input routing logic configured to allocate compatible functional signals to shared input test registers in response to corresponding state transitions having different source states and in response to a destination state of one state transition not being a source state of another state transition; a compressed output circuit including a plurality of shared output test registers; a plurality of logic gates coupled to the shared output test registers; and output routing logic configured to allocate compatible state signals to shared output test registers in response to corresponding states having no direct transition relationship; and an AFSM core coupled between the compressed input circuit and the compressed output circuit.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a state diagram of an Asynchronous Finite State Machine (AFSM);

FIG. 2 is a schematic of a scan collar architecture for an Asynchronous Finite State Machine (AFSM);

FIG. 3 is a simplified circuit diagram of an embodiment compressed input circuit;

FIG. 4 is a simplified circuit diagram of an embodiment compressed output circuit;

FIG. 5 is a flowchart of an embodiment method for developing an iterative algorithm to optimize the final Design for Test (DFT) architecture and merge functional test signals to the same input test register;

FIG. 6 is a flowchart of an embodiment method for a redistribution process; and

FIG. 7 is a flowchart of an embodiment method for developing an iterative algorithm to optimize the final Design for Test (DFT) architecture and merge output signals of AFSM to be observed using the same output test register.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of asynchronous finite state machines for control logic in mixed-signal and power devices, it should also be appreciated that these inventive aspects may also apply to other asynchronous sequential circuits, clockless digital logic designs, and self-timed circuits. In particular, aspects of this disclosure may similarly apply to asynchronous pipelines, bundled-data circuits, delay-insensitive circuits, quasi-delay-insensitive circuits, and speed-independent circuits that require testing infrastructure for manufacturing verification.

Aspects of the disclosure provide techniques for optimizing Asynchronous Finite State Machines (AFSMs) test architectures through a compressed scan collar design. The scan collar architecture merges the activation of state transitions at the input of the AFSM and state observation compression at the output of the AFSM to minimize test infrastructure overhead while maintaining fault coverage. Unlike approaches that map each state transition activation and state outputs to dedicated test registers, the compressed architecture leverages graph topology analysis to share components across compatible transition activations and state observations.

In embodiments, the proposed compressed scan collar architecture implements transition control through merged trigger functions based on a compatibility analysis. Arcs in the state transition graph can share input test registers when they meet two conditions: they originate from different source states, and their source states are not destinations of other transitions. This compatibility-based merging establishes a theoretical minimum bound for the number of control registers equal to the maximum state fanout plus one. The approach eliminates redundant control points present in conventional one-to-one mapping schemes.

In embodiments, state observation compression reduces test infrastructure by allowing multiple states to share observation points. The same output test register can monitor states that are not directly coupled through transitions in the graph. The architecture ensures that every state transition produces an observable change in at least one observation point, maintaining complete visibility of state changes for fault detection. Observing compression can consider direct and indirect state coupling to determine compatible state groupings.

Advantageously, the compressed architecture reduces silicon area footprint and test application time. For example, area reductions can be achieved through register count reduction compared to conventional approaches. Further, shorter scan chains directly translate to faster test pattern application and response collection.

In embodiments, systematic algorithms enable practical implementation of the compressed scan collar. The trigger merging algorithm employs conflict matrix analysis and iterative partitioning to identify compatible function groups. A similar graph-based algorithm can be used to determine optimal state observation groupings. Both algorithms can include mechanisms to handle corner cases and ensure convergence to valid solutions that maintain testability.

In embodiments, the architecture supports comprehensive testing of the AFSM core functionality and surrounding combinational logic. Input function testing utilizes shared control points across primary inputs, while output monitoring employs optimized observation point partitioning. The complete test infrastructure enables thorough fault coverage while minimizing area impact through strategic resource sharing. These and additional details are further discussed below.

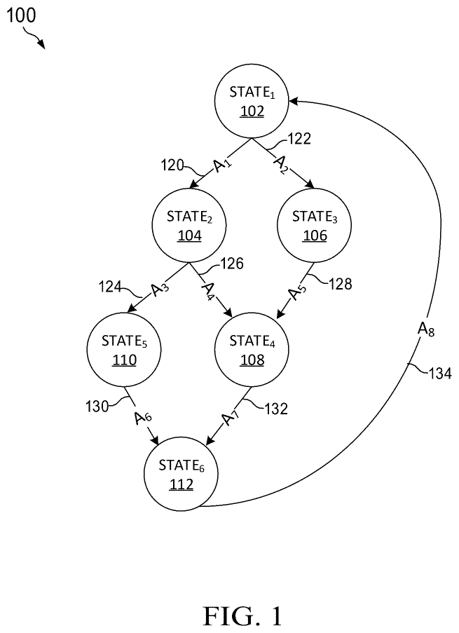

FIG. 1 illustrates a state diagram of an Asynchronous Finite State Machine (AFSM) 100. The AFSM 100 includes six states: a first state (STATE₁) 102, a second state (STATE₂) 104, a third state (STATE₃) 106, a fourth state (STATE₄) 108, a fifth state (STATE₅) 110, and a sixth state (STATE₆) 112. The states are coupled through eight arcs (A₁ through A₈), where each are represents a transition from one state to another.

In embodiments, AFSM 100 provides control logic for analog devices in mixed signal applications. The AFSM 100 can manage power and analog devices with digital logic to achieve rapid input response times while maintaining low power consumption. In synchronous digital systems, power consumption increases proportionally with clock frequency since power directly relates to the clock rate. Sequential digital circuits use clock frequency to determine operational speed and corresponding power usage.

The AFSM 100 operates without a clock for its functional components, relying instead on combinational logic transitions. Due to this clockless operation, the logic implementation needs to be glitch-free. Since the combinational functions operate at high speeds, any glitches during state transitions can be incorrectly interpreted as triggers by the AFSM 100, potentially causing unintended state changes.

The AFSM 100 implements a 1/N coding scheme, also known as one-hot encoding, rather than traditional binary state encoding. In this encoding approach, each state corresponds to a dedicated sequential element. The number of sequential elements in the AFSM 100 matches the total number of states in the finite state machine, each representing a unique state.

While FIG. 1 shows an AFSM 100 with six states and eight arcs arranged in a specific configuration, this implementation is provided as an example only. Embodiments of the disclosure may include AFSMs with fewer or greater numbers of states and arcs arranged in different configurations based on specific application requirements. The number of states, the number of arcs out of or into each state, and the overall topology of the state transitions can vary depending on the desired functionality and complexity of the AFSM implementation.

From the first state (STATE₁) 102, two arcs are possible: a first arc (A₁) 120 to the second state (STATE₂) 104 and a second arc (A₂) 122 to the third state (STATE₃) 106, demonstrating that a single state can have multiple arcs leading out to different destination states. The second state (STATE₂) 104 includes two outgoing arcs: a third arc (A₃) 124 to the fifth state (STATE₅) 110 and a fourth arc (A₄) 126 to the fourth state (STATE₄) 108. The third state includes a fifth arc (A₅) 128 to the fourth state (STATE₄) 108. From the fifth state (STATE₅) 110, the sixth arc (A₆) 130 leads to the sixth state (STATE₆) 112, while the fourth state (STATE₄) 108 can transition to the sixth state (STATE₆) 112 through the seventh arc (A₇) 132. The sixth state (STATE₆) can transition back to the first state (STATE₁) through the eighth arc (A₈) 134.

The fourth state (STATE₄) 108 illustrates that a single state can have multiple incoming arcs, as it can be reached through either the fourth arc (A₄) 126 from the second state (STATE₂) 104 or the fifth arc (A₅) 128 from the third state (STATE₃) 106. Similarly, the sixth state (STATE₆) 112 can be reached through either the sixth arc (A₆) 130 from the fifth state (STATE₅) 110 or the seventh arc (A₇) 132 from the fourth state (STATE₄) 108.

Each arc (A₁ through A₈) represents a transition that, when a particular condition is met, triggers the corresponding state change. Being in a particular state is a prerequisite for enabling the arcs that originate from that state.

When digital logic complexity reaches certain thresholds, pattern-based testing can become necessary to verify functionality and manufacturing quality. For testing AFSMs, Design for Testability (DFT) logic can add test data, enable computation result comparison with expected values, control transitions between states through DFT control points, and monitor active states via DFT observe points. The DFT logic, based on flip-flops and multiplexers, can impact the AFSM's overall size.

While functional testing of the AFSM would require operation of the complete system to check its performance, such testing can make it difficult to verify all possible conditions and may overlook potential faults. Additionally, functional testing can be time-consuming and restricted by the need to install and test other components that provide input signals.

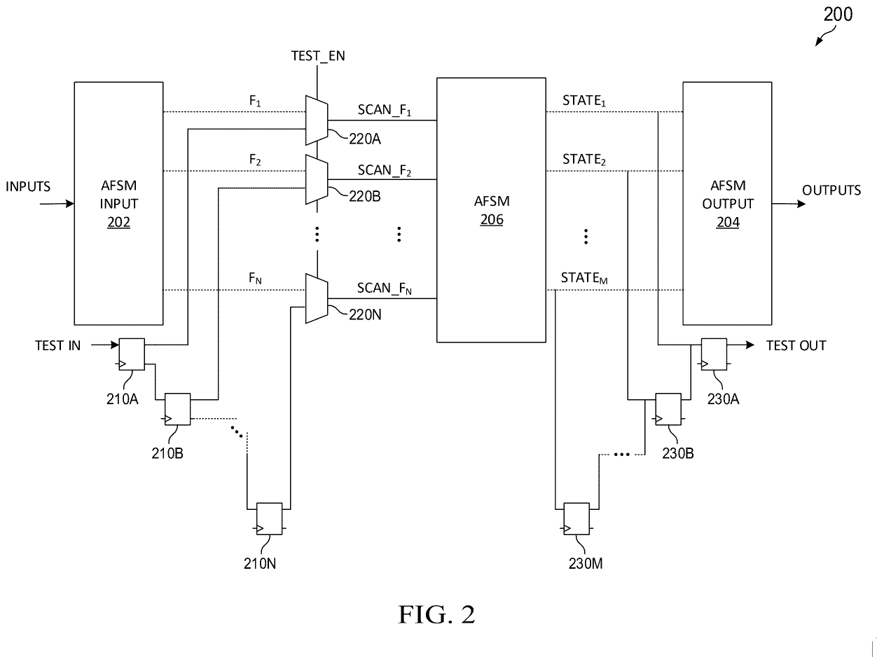

Instead, these functions can be directly controlled during test mode through a scan collar architecture, as shown in FIG. 2, to verify proper state transition behavior and detect potential manufacturing defects.

FIG. 2 illustrates a schematic of a scan collar architecture 200 for an Asynchronous Finite State Machine (AFSM) 206. The scan collar architecture 200 includes an AFSM input circuit 202 for processing functional signals (F₁-F_{N}) during normal operation, an AFSM output circuit 204 for handling the state output signals, and the AFSM 206 under test. AFSM 206 may be implemented as the AFSM 100 in FIG. 1.

An example implementation of the scan collar architecture 200 is disclosed in U.S. Pat. No. 12,032,460, which is incorporated herein by reference in its entirety.

The AFSM 206 receives functional scan signals (SCAN_F₁ through SCAN_F_{N}) that activate state transitions. The functional scan signals (SCAN_F₁ through SCAN_F_{N}) may correspond to a functional signal (F₁-F_{N}) originating from the AFSM input circuit 202 or test input (TEST IN) signals originating from test equipment, such as a test controller or an off-chip Automatic Testing Equipment (ATE).

The functional signals (F₁-F_{N}) can originate from various components of a device or system, such as sensors or other components, and may undergo various processing and conversion (such as conversion to digital signals) before being transmitted to the AFSM 206 through the AFSM input circuit 202 and the multiplexers (220A-N).

In response to the AFSM 206 receiving a functional scan signal, whether it originates from the AFSM input circuit 202 or the test equipment, a state transition is triggered (i.e., activated) based on the specific functional scan signal. The AFSM 206 produces state signals (STATE₁ through STATE_{M}) that indicate its current state, which may be represented through an encoding (e.g., one-hot encoding) and provided to additional logic to produce outputs.

For example, in an example of implementing the AFSM 100 as AFSM 206, the AFSM 100 transitions from the first state (STATE₁) to the second state (STATE₂) through the first arc (A₁) 120 in response to receiving the first functional scan signal (SCAN_F₁), transitions from the first state (STATE₁) to the third state (STATE₃) through the second arc (A₂) 122 in response to receiving the second functional scan signal (SCAN_F₂), transitions from the second state (STATE₂) to the fifth state (STATE₅) through the third arc (A₃) 124 in response to receiving the third functional scan signal (SCAN_F₃), transitions from the second state (STATE₂) to the fourth state (STATE₄) through the fourth arc (A₄) 126 in response to receiving the fourth functional scan signal (SCAN_F₄), transitions from the third state (STATE₃) to the fourth state (STATE₄) through the fifth arc (A₅) 128 in response to receiving the fifth functional scan signal (SCAN_F₅), transitions from the fifth state (STATE₅) to the sixth state (STATE₆) through the sixth arc (A₆) 130 in response to receiving the sixth functional scan signal (SCAN_F₆), transitions from the fourth state (STATE₄) to the sixth state (STATE₆) through the seventh arc (A₇) 132 in response to receiving the seventh functional scan signal (SCAN_F₇), and transitions from the sixth state (STATE₆) to the first state (STATE₁) through the eighth arc (A₈) 134 in response to receiving the eighth functional scan signal (SCAN_F₈).

Accordingly, the test infrastructure implements a scan collar configuration surrounding the AFSM 206, enabling testing of the AFSM 206 by controlling state transitions through the functional scan signals and observing state changes.

During functional mode, functional signals (F₁-F_{N}) from the scan collar directly activate state transitions, while output signals from the AFSM 206 indicate the current state, allowing observation of state transitions. During test mode, the test input (TEST IN) signals from the input test registers (210A-N) activate the state transitions instead of testing input functions, while output signals from the AFSM 206 indicate the current state, allowing observation of state transitions. The scan collar architecture enables the detection of manufacturing defects and verification of state transition behavior while preventing undesired state changes during test pattern loading.

For testing, the scan collar architecture 200 includes N input test registers (210A-N), N multiplexers (220A-N), and M output test registers (230A-M), where N and M are integers greater than 1. In the uncompressed implementation, N corresponds to the number of arcs in AFSM 206, and M corresponds to the number of states. Accordingly, N and M can vary depending on factors such as the complexity of the AFSM 206, the number of states and transitions to be tested, and specific testing requirements.

Each of the N number of input test registers (210A-N) is linked to one of the functional scan signals (SCAN_F₁ through SCAN_F_{N}), which activates a corresponding state transition in the AFSM 206 from one state to another.

For example, in the uncompressed implementation, when implementing the scan collar architecture 200 for AFSM 100, which has eight arcs (A₁ through A₈) and six states (STATE₁ through STATE), N would equal 8 and M would equal 6. Each are has a corresponding functional scan signal, input test register, and multiplexer, while each state has a corresponding output test register for observation.

In embodiments, the AFSM input circuit 202 includes input logic, defining when and how the functional signals (F₁-F_{N}) are produced based on the functional input (INPUT) signals. A given functional signal may be triggered in response to predefined conditions being met. The conditions can be defined differently for different embodiments, depending on the desired function and complexity of the AFSM configuration. In embodiments, the functions may be used for encoding a function. For example, functional input signals encoded as ‘1011’ can trigger an eleventh functional scan signal (SCAN_F₁₁) at the AFSM 206.

For testing, the input side of the architecture includes N input test registers 210A-N arranged in a scan chain configuration, forming a daisy chain structure. The input test registers 210A-N are configured to receive test input (TEST IN) signals. In embodiments, the input test registers 210A-N can operate in either shift mode for loading test patterns or capture mode for applying test values. In embodiments, the input test registers 210A-N are togglable between the shift and capture modes through a select signal from a selection port through the test equipment.

The test data (TEST IN) signal may be loaded into the input test register 210 from the test equipment. The input test register 210 can be coupled to an input interface to receive the test data. In embodiments, the test data may be loaded into the input test register 210 one bit at a time. For example, while in shift mode, the test data may be loaded on a first clock pulse into the first input test register 210A, shifted on a second clock pulse to the second input test register 210B, and so forth until the N^{th} input test register 210N.

In embodiments, the input test registers 210A-N may operate in capture mode, where test data is provided to the multiplexers 220A-N from the input test registers 210A-N. For example, when the first capture signal data is received by the first multiplexer 220A from the first input test register 210A, the second capture signal data is received by the second multiplexer 220B from the second input test register 210B, and so forth, up to the N^{th} capture signal data is received by the N^{th} multiplexer 220N from the N^{th} input test register 210N. In this manner, test data can be provided to the AFSM 206 through the multiplexers 220A-N from the input test registers 210A-N.

In embodiments, the input test registers 210A-N receive clock signals. In shift mode, the test data may be shifted through each input test register 210 on each clock cycle. In embodiments, the clock cycle is provided by the test equipment through a clock port.

A set of N multiplexers 220A-N provide the switching mechanism between functional signals and test input (TEST IN) signals. When the test enable (TEST_EN) signal is asserted (i.e., test mode), the multiplexers (220A-N) forward test values from their associated input test registers to AFSM 206 to activate specific functional scan signals (SCAN_F₁ through SCAN_F_{N}). When the test enable (TEST_EN) signal is de-asserted (i.e., functional mode), the multiplexers route the functional signals (F₁-F_{N}) from the AFSM input circuit 202 to AFSM 206 as the functional scan signals (SCAN_F₁ through SCAN_F_{N}).

The AFSM 206 outputs state signals to the output test registers 230A-M and the AFSM output circuit 204. The state signals indicate the state of the AFSM 206. For example, when the AFSM 206 is in a first state (STATE₁), the state signal outputted from the AFSM 206 is the first state (STATE₁) signal. In embodiments, the state signals may be used for encoding. For example, output signals encoded as ‘1011’ can indicate that the AFSM 206 is in its eleventh state (STATE₁₁).

In embodiments, the AFSM output circuit 204 includes output logic that receives the state signals from the AFSM 206 and generates output signals depending on the observed state of the AFSM 206.

In embodiments, the output side of the architecture includes M output test registers 230A-M. These output test registers capture AFSM states (STATE₁ through STATE_{M}) during testing. The output test registers 230A-M can store the state of the AFSM 206. In embodiments, the output test registers 230A-M can operate in either shift or capture modes. In embodiments, the output test registers 230A-M are togglable between the shift and capture modes through a select signal from a selection port through the test equipment. In embodiments, the select signal of the input test registers 210A-N and the select signal of the output test registers 230A-M are synchronized such that the input and output scan registers operate synchronously.

In shift mode, the state output from the AFSM 206 is outputted serially as the test out (TEST OUT) signal, which can be observable at an output port in some embodiments by the test equipment. In capture mode, the data can be loaded from the AFSM 206 to the output test registers 230A-M.

The first output test register 230A receives the first state (STATE₁) signal, the second output test register 230B receives the second state (STATE₂) signal, and so forth, up to the M^{th} output test register 230M, which receives the M^{th} state (STATE_{M}) signal.

The output state data can be compared with the expected state of the AFSM 206 to determine whether it is operating properly. If the state data matches the simulated results, the internal logic of the AFSM 206 is operating correctly. However, if the results do not match, an error signal may be triggered, indicating a fault condition.

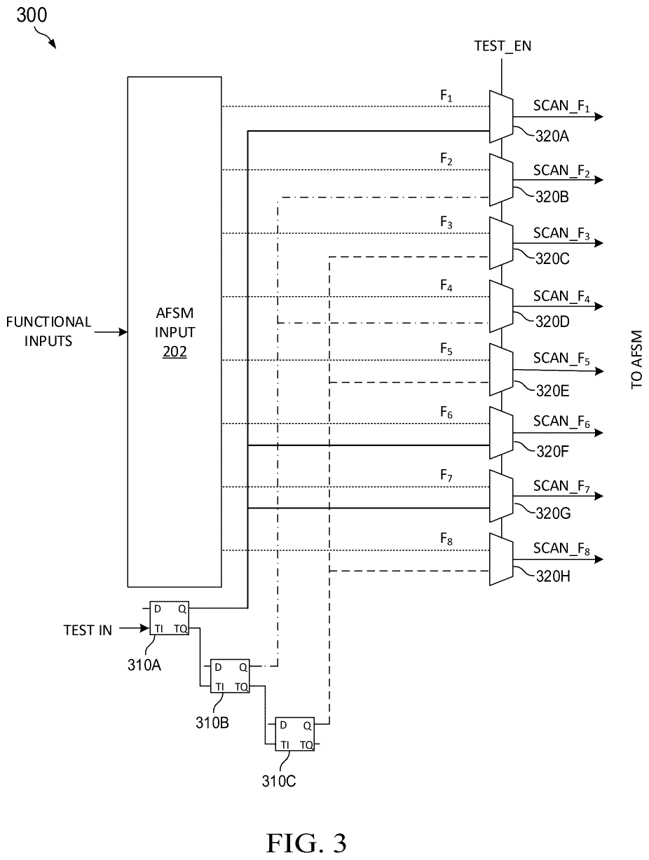

FIG. 3 illustrates a simplified circuit diagram of an embodiment compressed input circuit 300, which can replace the test input side of the scan collar architecture 200 in a compressed implementation. The compressed input circuit 300 reduces the number of input test registers in the scan collar architecture 200 of FIG. 2 by merging the activation of functional scan signals of uncorrelated arcs, resulting in circuit footprint and test time reductions.

Using one input test register for each functional scan signal (SCAN_F₁ through SCAN_F_{N}) corresponding to each are of the AFSM 206, as implemented in the uncompressed implementation shown in FIG. 2, can be redundant since only the current active state can take transitions at any given time.

For example, when AFSM 100 of FIG. 1 is in the first state (STATE₁) 102, the first functional scan signal (SCAN_F₁) and the second functional scan signal (SCAN_F₂) can be triggered to activate the transition from the first state (STATE₁) 102 to the second state (STATE₂) 104 through the first arc (A₁) 120 and from the first state (STATE₁) to the third state (STATE₃) 106 through the second arc (A₂) 122, respectively, while the other functional scan signals (SCAN_F₃ through SCAN_F₈) cannot be activated since their source states (i.e., STATE₂ through STATE) are inactive. Accordingly, having dedicated input test registers for each functional scan signal (SCAN_F₁ through SCAN_F_{N}) is inefficient, as many of these registers cannot influence state transitions from the current active state.

In embodiments, the inefficiency of the uncompressed implementation, as discussed in FIG. 2, is addressed by reconfiguring the architecture to allow for multiple functional scan signals (SCAN_F₁ through SCAN_F_{N}) to share the same input test register based on specific compatibility rules. This way, multiple arcs can be triggered using the same input test register. The proposed compatibility rules include: functional scan signals (SCAN_F₁ through SCAN_F_{N}) can share an input test register when they do not have the same source state and if a state is a destination of one functional scan signal, any functional scan signal originating from that state cannot share an input test register with the incoming functional scan signal.

For example, in the AFSM 100 of FIG. 1 and its embodiment of FIG. 2, the third functional scan signal (SCAN_F₃) and the fourth functional scan signal (SCAN_F₄), which trigger the state transition from the second state (STATE₂) 104 to the fifth state (STATE₅) 110 through the third arc (A₃) 124 and from the second state (STATE₂) 104 to the fourth state (STATE₄) through the fourth arc (A₄) 126, cannot share an input test register since they share same source state (STATE₂).

Likewise, the first functional scan signal (SCAN_F₁) cannot share an input test register with the third functional scan signal (SCAN_F₃) and the fourth functional scan signal (SCAN_F₄), as the second state (STATE₂) is the destination of the first functional scan signal (SCAN_F₁) and the originating state for the third functional scan signal (SCAN_F₃) and the fourth functional scan signal (SCAN_F₄).

Accordingly, when implemented for the AFSM 100, the compressed input circuit 300 includes three input test registers 310A-C and eight multiplexers 320A-H for the eight arcs (A₁-A₈) of AFSM 100. As previously discussed regarding the scan collar architecture 200, the AFSM input circuit 202 provides the functional signals (F₁ through F₈) to respective multiplexers 320A-H.

The input test registers 310A-C are coupled in a daisy chain configuration where each subsequent register's test input (TI) receives the test output (TQ) from the previous register. The data output (Q) of each input test register 310 is coupled to multiple multiplexers based on the defined compatibility rules, as indicated by the different line styles (solid, dashed, and dash-dot) showing the coupling patterns from each input test register's output to the multiplexers. In an embodiment, test output (TQ) and data output (Q) can be the same output of the test register. In embodiments, test input (TI) and data input (D) can be the same input of the test register.

For example, the output (Q) of the first input test register 310A is coupled to the first multiplexer 320A, the sixth multiplexer 320F, and the seventh multiplexer 320G, indicating that these multiplexers control compatible functional scan signals that can share the same test register. Similarly, the output (Q) of the second input test register 310B is coupled to the second multiplexer 320B and the fourth multiplexer 320D. The output (Q) of the third input test register 310C is coupled to the third multiplexer 320C, the fifth multiplexer 320E, and the eighth multiplexer 320H.

The compression of test registers follows a theoretical minimum bound determined by the maximum state fanout plus one, where state fanout refers to the maximum number of arcs originating from a state considering all the states of the AFSM. This bound ensures sufficient registers can control all possible transitions while maintaining complete test coverage.

For example, in the AFSM 100 shown in FIG. 1, the maximum number of states fanouts is two as the first state (STATE₁) 102 and the second state (STATE₂) 104 each have two outgoing arcs and every other state having a single outgoing arc, thus the theoretical minimum number of input test registers for the compressed implementation of the scan collar architecture is three.

In embodiments, the input combinational logic networks can be tested using standard test-point insertion techniques. For example, primary inputs can share control points to optimize test coverage while minimizing area overhead. The distribution and optimization of these test points can be implemented to minimize circuit area footprint with minimal fault coverage loss by partitioning the input signals to share test points.

The partitioning of primary inputs for test point sharing can follow optimization principles. Inputs can be grouped to share test points to minimize potential fault coverage loss. Further, primary inputs involved in generating common functions can be assigned to different test point partitions. This partitioning strategy can ensure efficient testing of the input combinational logic while maintaining minimal area impact from the additional test infrastructure.

This optimized test point insertion approach can thoroughly test the input combinational logic without requiring dedicated test points for each primary input. The shared test points and the compressed scan architecture for function testing provide comprehensive fault coverage of the input logic and state transition behavior while minimizing overall test infrastructure overhead.

Although the configuration of the compressed input circuit 300 is shown for the AFSM 100 (having eight functions F₀ through F₇ and six states (STATE₁ through STATE₆) to simplify discussion, it should be appreciated that the principles discussed regarding the compressed input circuit 300 applies to any other AFSM configuration with different numbers of states and functions based on the compatibility rules discussed above.

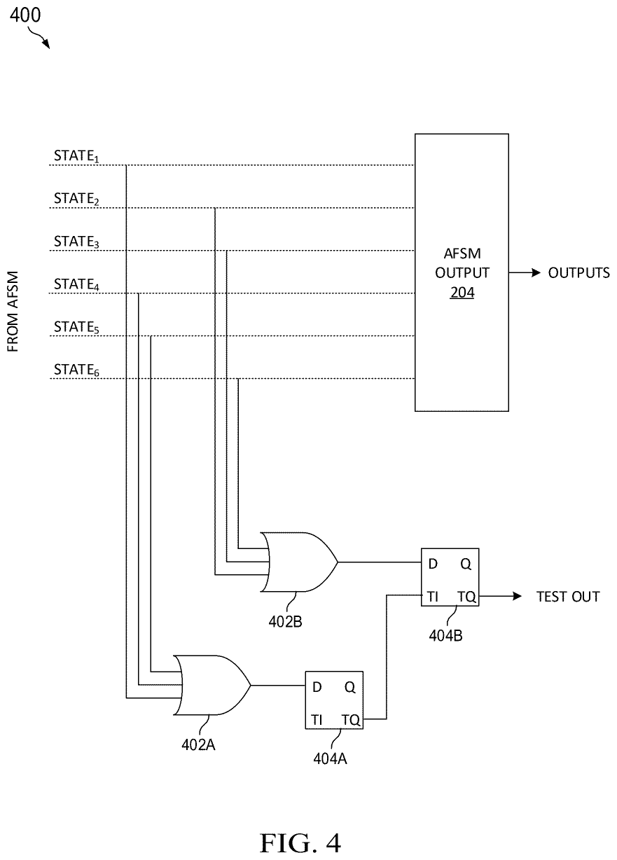

FIG. 4 illustrates a simplified circuit diagram of an embodiment compressed output circuit 400, which can replace the output side of the scan collar architecture 200 in a compressed implementation. The compressed output circuit 400 reduces the quantity of the output test registers compared to the scan collar architecture 200 of FIG. 2, resulting in circuit footprint and test time reductions.

The reduction in circuit footprint and test time reduction of the scan collar architecture 200 can be extended to state observation at the output side of the scan collar. The number of output test registers can be reduced while maintaining the ability to detect fault by capturing value changes for every state transition in the AFSM 206.

Similar to the compressed input circuit 300, the output test registers of the scan collar architecture 200 can be redundant in some implementations of the AFSM 206. Accordingly, it is proposed that AFSM states that are not directly coupled through an are can be observed by the same output test register. In this way, the number of output test registers can be reduced by coupling a single output test register to a logic gate (e.g., an OR gate as shown in FIG. 4), which receives multiple output state signals from the AFSM 206 at its input.

The partitioning of outputs can follow an optimization principle: outputs driven by states connected through arcs can be assigned to different observation points. This partitioning ensures that state transitions always result in observable value changes at the observation points, as states that can transition between each other cannot share the same observation path. Through this optimized observation point structure, the output combinational logic can be thoroughly tested while minimizing the test infrastructure overhead.

For example, in AFSM 100, the first state (STATE₁) 102, the fifth state (STATE₅) 110, and the fourth state (STATE₄) 108 can share a first output test register 404A, since no arc directly connects these states. Similarly, the second state (STATE₂) 104, the third state (STATE₃) 106, and the sixth state (STATE₆) 112 can share a second output test register 404B. This compression in the number of output test registers reduces the number of required observation points from six (one per state) to two while maintaining the ability to detect all state transitions.

In FIG. 4, in addition to the first output test register 404A and the second output test register 404B, the compressed output circuit 400 includes a first OR gate 402A and a second OR gate 402B. The first OR gate 402A receives state signals from states that are not directly connected through a state transition: the first state (STATE₁) 102, the fifth state (STATE₅) 110, and the fourth state (STATE₄) 108. The output of the first OR gate 402A is coupled to the data input (D) of the first output test register 404A. Similarly, the second OR gate 402B receives state signals from another group of states that are not directly connected through a state transition: the second state (STATE₂) 104, the third state (STATE₃) 106, and the sixth state (STATE₆) 112. The output of the second OR gate 402B is coupled to the data input (D) of the second output test register 404B.

The first output test register 404A and the second output test register 404B are arranged in a daisy chain configuration where the output (Q) of the first output test register 404A is coupled to the test input (TI) of the second output test register 404B. The test output (TQ) of the second output test register 404B provides the test out (TEST OUT) signal, which can be analyzed to verify proper state transitions of the AFSM 206.

The distribution and optimization of output observation points can utilize logic gates (e.g., XOR trees) combined with optimized output partitioning. This approach allows multiple primary outputs to share observation points while maintaining fault coverage. The logic gate structure (e.g., XOR tree structure) enables an efficient combination of multiple output signals into a reduced number of observation points.

Unlike the compression in the compressed input circuit 300, where a minimum bound can be calculated based on state fanout, the compression of state observation points follows the rule of avoiding shared observation for directly coupled states. Accordingly, the number of required output test registers depends on the specific connectivity pattern of the AFSM states. This approach ensures that any state transition will result in at least one observable value change in the output test registers, enabling complete fault detection coverage.

Fault coverage in the compressed scan collar architecture remains comprehensive despite reducing test infrastructure through strategically sharing test resources. For input compression, complete controllability of state transitions is maintained since functional signals share input test registers only when their source states are mutually exclusive-meaning only one shared transition can be active at anytime based on the current state. The compatibility rules ensure that all other potentially conflicting transitions are properly blocked when testing a particular state transition.

For output compression, complete observability is preserved by ensuring that states sharing an output test register cannot have direct transitions between them. Any state transition will result in a detectable change in at least one output test register value. The logic gate (i.e., OR gate) structure in the output compression combines state signals. A transition between two states produces an observable change in the compressed observation points.

The architecture can detect stuck-at, transition, and path delay faults through these sharing mechanisms while reducing the overall test infrastructure footprint. The compressed architecture can achieve equivalent fault coverage to an uncompressed implementation while using fewer test registers.

In embodiments, the output combinational logic networks in AFSM output circuit 204 can be tested using standard test-point insertion techniques through shared observation points among primary outputs. Like input side compression, strategically sharing observation points enables efficient testing while minimizing area overhead.

Although the configuration of the compressed output circuit 400 is shown for the AFSM 100 (having eight arcs and six states) to simplify discussion, it should be appreciated that the principles discussed concerning the compressed output circuit 400 applies to any other AFSM configuration with different numbers of states and transitional configurations based on the compatibility rules discussed above.

Further, while OR gates are shown as an example implementation, other logic gates or combinations of logic gates can be used in various embodiments to combine the state signals, as long as the logic configuration ensures that state transitions produce detectable changes at the observation points.

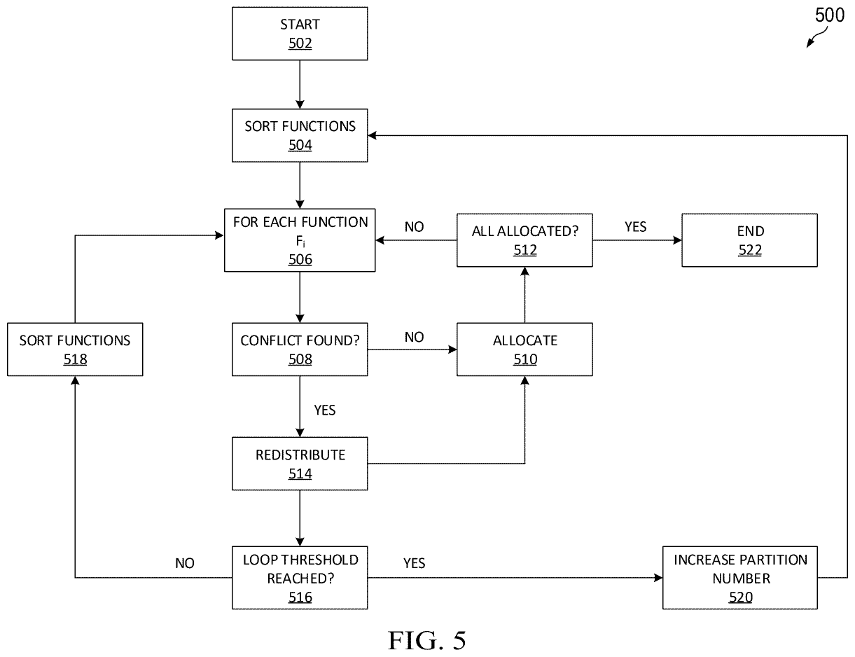

FIG. 5 illustrates a flowchart of an embodiment method 500 for developing an iterative algorithm to optimize the final Design for Test (DFT) architecture and merge functional test signals to the same input test register. Method 500 proposes a heuristic merging approach for determining the optimal number of input test registers to partition the triggers for activating a state transition in the AFSM based on specific criteria. Accordingly, the merging approach is a partitioning problem with a compatibility function.

Given a target number of input test registers to be inserted, the proposed method aims to determine an optimal partitioning of the functional signals matching the target number of inputs test registers. This results in a minimum number of partitions (i.e., minimal number of input test registers) without generating a conflict between active and blocked arcs within a partition.

In method 500, a set of functional signals (F₁ through F_{T}) are defined where each functional signal (Fᵢ) triggers the activation of one or more are transitions in the AFSM, where T is an integer greater than one and equal to the number of arcs of the AFSM. A functional signal results from a combinational function driven by primary inputs, though this combinational logic is not relevant for testing arcs and states.

A criterion is defined where to test a state transition from one state to another through an arc, the are is activated without activating a transition from the other state to any other state—effectively blocking the activation of an are from the output state.

For example, concerning the AFSM 100, to test the state transition from the first state (STATE₁) 102 to the second state (STATE₂) 104, the first arc (A₁) 120 is activated through the functional scan signal (SCAN_F₁) while actively blocking the activation of the third functional scan signal (SCAN_F₃) and the fourth functional scan signal (SCAN_F₄), to block the activation of a transition from the second state (STATE₂) 104 to the fifth state (STATE₅) 110 through the third arc (A₃) 124 and to the fourth state (STATE₄) 108 through the fourth arc (A₄) 126, respectively.

The criterion can be implemented through a bi-dimensional conflict matrix that expresses the compatibility between the functional signal (Fᵢ) and each arc (Aᵢ) of the AFSM. The conflict matrix represents the relationship between arcs in an AFSM state transition diagram and the functional signals that trigger those transitions. Each column of the matrix corresponds to a specific arc in the AFSM, representing a transition from one state to another. Each row corresponds to a functional signal.

The entries within the matrix indicate the association between a functional signal and an arc. For each cell, a value of ‘1’ signifies that the functional signal corresponding to that row triggers the state transition represented by the column's arc. A zero or blank entry (‘0’) indicates that the functional signal has no relationship with that transition. A value of ‘−1’ signifies that the functional signal corresponding to that row is to be blocked when the state transition represented by the column's are is triggered.

For example, the first and last row of the conflict matrix for the AFSM 100 can be represented in the matrix:

$$conflict\_matrix = \{ \begin{matrix}1 & - 1 & - 1 & - 1 & 0 & 0 & 0 & 0 \\ ⋮ & ⋮ & ⋮ & ⋮ & ⋮ & ⋮ & ⋮ & ⋮ \\ - 1 & - 1 & 0 & 0 & 0 & 0 & 0 & 1\end{matrix} .$$

By examining the first row of the conflict matrix, one can determine that when testing the transition from the first state (STATE₁) 102 to the second state (STATE₂) 104 through the first arc (A₁) 120, the first functional signal (F₁) is activated while the second functional signal (F₂), the third functional signal (F), and the fourth functional signal (F₄) are blocked. This relationship is captured in the conflict matrix where the first row, corresponding to the first functional signal (F₁), includes a value of ‘1’ in the first column, the value ‘−1’ in the second, third, and fourth columns, and a value of ‘0’ in the fifth, sixth, seventh, and eighth columns.

Likewise, when testing the transition from the sixth state (STATE₆) 112 to the first state (STATE₁) 102 through the eight arc (A₈) 134, the eighth functional signal (F₈) is activated while the first functional signal (F₁) and the second functional signal (F₂) are blocked. This relationship is captured in the conflict matrix where the last row, corresponding to the eighth functional signal (F₈), includes a value of ‘−1’ in the first column and second column, the value ‘1’ in the last column, and a value of ‘0’ in the third, fourth, fifth, sixth, and seventh columns.

It should be appreciated that the use of ‘1’, ‘−1’, and ‘0’ values in the conflict matrix represents an example implementation for expressing relationships between functional signals and state transition arcs. In various embodiments, different numerical values, binary representations, or other encoding schemes can be used to represent these relationships, as long as the chosen representation scheme maintains the ability to identify activation, blocking, and non-relationship conditions between functional signals and state transitions. The specific values or encoding methods can be selected based on implementation requirements, optimization goals, or tool compatibility considerations while preserving the fundamental relationship identification capabilities needed for the compression analysis.

Method 500 starts at step 502, which is an initialization step. At step 502, the number of partitions is initially set to a tentative value equal to the theoretical minimum bound for the number of required test registers, which, as previously indicated, is equal to the maximum state fanout plus one. For example, in AFSM 100, where the maximum state fanout is two, the initial number of partitions is set to three. Further, a counter value (i) is initialized to one.

At step 504, the functional signals (F₁ through F_{T}) are sorted based on a conflict value, starting from the functional signal with the highest conflict value to the functional signal with the least conflict value. In this context, a conflict value for a functional signal is defined as the number of functional signals that conflict with that functional signal. The conflict value can be determined based on the values ‘1’ and ‘−1’ being in the same column of the conflict matrix when determining a conflict between two functional signals. This is because the same functional signal cannot simultaneously be active (i.e., triggering) and in a blocked state.

For example, in the AFSM 100, the first functional signal (F₁) conflicts with the last functional signal (F₈) because the conflict matrix has a value of ‘1’ in the first row of the first column and a value of ‘−1’ in the last row of the first column. The functional signal with the highest conflict value is assigned an index value equal to one and the functional signal with the lowest conflict value is assigned the value of T.

At step 506, the optimization process examines the partition set to find the first available partition that can accommodate the functional signal corresponding to the current counter value without conflicts with other functional signals already allocated to that partition. The search ensures there are no conflicting functional signals already allocated to the candidate partition.

During the initial optimization round, the functional signal with the highest conflict value receives index one and can be allocated to the first partition, as all partitions are empty. In subsequent rounds, the process attempts to place each indexed functional signal into existing partitions. For instance, the functional signal with index two may be assigned to the first partition if no conflicts exist with the previously allocated functional signal. If a conflict exists, the signal is evaluated for placement in the second partition, continuing this pattern for remaining signals.

At step 508, if every available partition has already been allocated a functional signal that conflicts with the current functional signal being evaluated, the process advances to step 514. However, when a compatible partition is found, the current functional signal is allocated to that available partition at step 510.

At step 512, in response to at least one functional signal not yet allocated to a partition, the optimization process returns to step 506. However, when all functional signals have been allocated to a partition, the optimization stops at step 522.

At step 514, in response to every available partition having a functional signal allocated to it that conflicts with the current functional signal being evaluated, the conflict is attempted to be resolved through a redistribution process.

The redistribution attempts to make available a partition within the set of available partitions for the current functional signal being evaluated by reordering the allocation of already allocated functional signals within the partitions such that allocating the current functional signal to the partition no longer results in a conflict.

The redistribution process determines whether one or more functional signals that have already been allocated to a partition and are in conflict with the current functional signal being evaluated can be moved to another partition without causing a new conflict. If the redistribution of existing allocated functional signals can be done without creating new conflicts, the existing allocated functional signal is allocated to the newly made available partition, resulting in the potential availability of the partition for the current functional signal to be allocated without any conflicts.

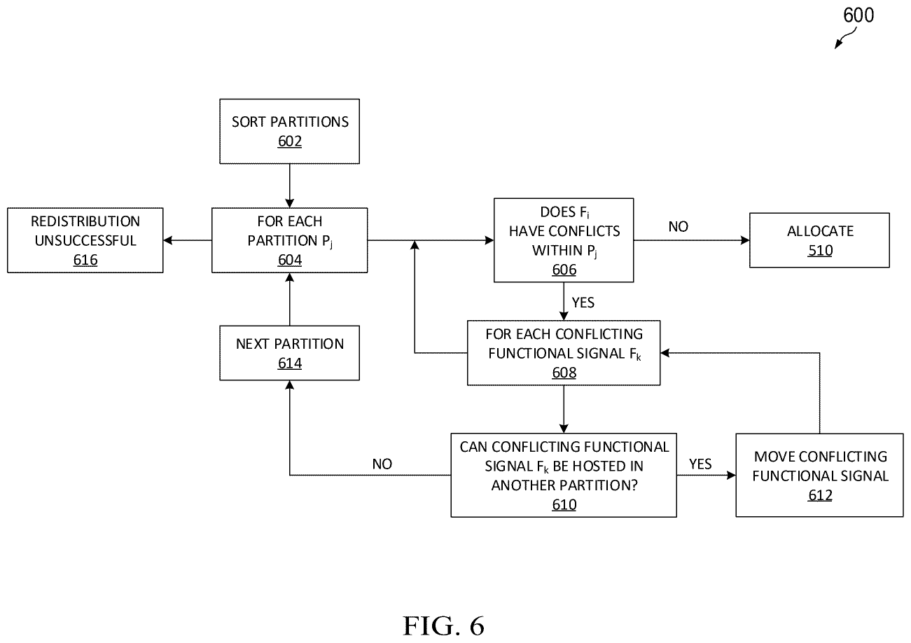

In response to the functional signal allocations being successfully reordered and reallocated within the existing partitions without creating conflicts, the optimization process transitions to step 510. As a partition has become available without any conflicting functional signals already allocated to it after the redistribution, the current functional signal is allocated to that available partition. An example of the redistribution process is described in method 600 of FIG. 6.

As the reordering of conflicting functional signals can be time consuming in complex AFSM cases, in embodiments, the redistribution process is limited by a threshold where even if the all partitions have not been evaluation but the threshold (e.g., time, processing resources, etc.) has been reached, the redistribution process is terminated. At step 516, a determination is made as to whether the unsuccessful reallocation at step 514 was after all partitions had been evaluated or whether the redistribution process was terminated due to the loop threshold being reached.

At step 518, in response to (1) the threshold not being exceeded in step 514 and (2) the functional signal allocations not being successfully reordered and reallocated within the existing partitions without creating conflicts, the functional signals (F₁ through F_{T}) are sorted based on a historical conflict value.

It should be observed that historical conflict value applied in sort function at step 518 is representative of the conflict between a functional signal and previous partitioning iterations, while the conflict value applied in the sort function at step 504 is representative of the number of conflicts between a functional signal and all the other functional signals. As an example, the historical conflict value of a functional signal can be given by the number of unsuccessful allocation iterations.

At step 520, in response to (1) the threshold being exceeding in step 514, and (2) the functional signal allocations not being successfully reordered and reallocated within the existing partitions without creating conflicts, an additional partition is added to the set of partitions. After adding the new partition, the allocation process returns to evaluate and assign the previously unsuccessful functional signal, maintaining the same counter value. The evaluation and allocation process begin again with the expanded set of partitions, allowing another attempt to place the functional signal that could not be allocated in the previous iteration. The counter index (i) is reset for the new set of partitions.

It is noted that all steps outlined in the method are not necessarily required and can be optional. Further, changes to the arrangement of the steps, removal of one or more steps and path connections, and addition of steps and path connections are similarly contemplated.

FIG. 6 illustrates a flowchart of an embodiment method 600 for a redistribution process, which can be implemented as step 514 in method 500. In method 600, the partitions are sorted from the partition with the greatest to the least number of conflicting functional signals with the current functional signal being evaluated (Fᵢ). For each conflicting functional signal within each partition, a determination is made as to whether it can be allocated to another partition without creating a new conflict. If it is possible to reallocate the conflicting functional signal to another partition and no conflicting functional signals remain allocated within a partition, method 600 returns to step 510 of method 500 for allocating the functional signal being evaluated to the partition.

At step 602, for the current functional signal being evaluated (Fᵢ), the partitions within the set of partitions are sorted by the number of conflicting functional signals already allocated to that partition. A first counter index (j) ranging from one to the total number of partitions (S) is initialized to the value of one.

The partition having the least number of conflicting functional signals is assigned an index of one, and the partition with the greatest number of conflicting functional signals is assigned an index of S, where S is an integer greater than one and equal to the total number of partitions.

At step 604, the partition having an index value equal to the counter index (j) is evaluated based on the current first counter index (j). If no functional signals allocated to the partition under evaluation conflict with the functional signal being evaluated, as determined at step 606, method 600 transitions to step 510 of method 500. At step 510, the functional signal being evaluated is allocated to the partition under evaluation from step 604.

If at step 606, it has been determined that one or more functional signals allocated to the partition under evaluation conflict with the functional signal being evaluated (Fᵢ), a second counter index (k) ranging from one to the total number of conflicting functional signals for the partition under evaluation is initialized to one.

At step 608, based on the current second counter index (k), each conflicting functional signal is evaluated for the partition under evaluation. If the current conflicting functional signal can be allocated to another partition at step 610, the current conflicting functional signal is reallocated at step 612 and the process transitions back to step 608 and the second counter index (k) is increased by one. If no more conflicts exist within the partition under evaluation the process transitions back to step 606 to determine whether the functional signal can be allocated within the partition under evaluation.

If, however, at step 610, it has been determined that the conflicting functional signal under evaluation cannot be reallocated to another partition, the process transitions to step 614 where the first counter index (j) is increased by one and then transitions to step 604 for the next partition to be evaluated. In embodiments, this process is repeated for all partitions.

If all partitions have been evaluated and no partitions are made available for allocation of the functional signal under evaluation, method 600 transitions from step 604 to step 616, indicating that the redistribution was unsuccessful. This allows the transition from the redistribution process to step 516 of method 600.

In embodiments, the redistribution includes a third counter that counts that number of loops within the redistribution process after each partition evaluation. If the third counter reaches a loop threshold, method 600 transitions to step 616 before evaluating the next partition. This is because there is a possibility that the redistribution may take an exceedingly long time to redistribute, given the various conflicts that may arise during the reordering. If the number of loops through the steps of method 600 exceeds the threshold loop, method 600 transitions to step 516 from step 616, indicating that the redistribution was unsuccessful and the loop threshold has been reached.

If the process determines that no partitions can be made available without the third counter reaching the loop threshold, method 600 returns to step 516 of method 500 from step 616, indicating that the redistribution was unsuccessful and the loop threshold has not been reached.

It is noted that all steps outlined in the method are not necessarily required and can be optional. Further, changes to the arrangement of the steps, removal of one or more steps and path connections, and addition of steps and path connections are similarly contemplated.

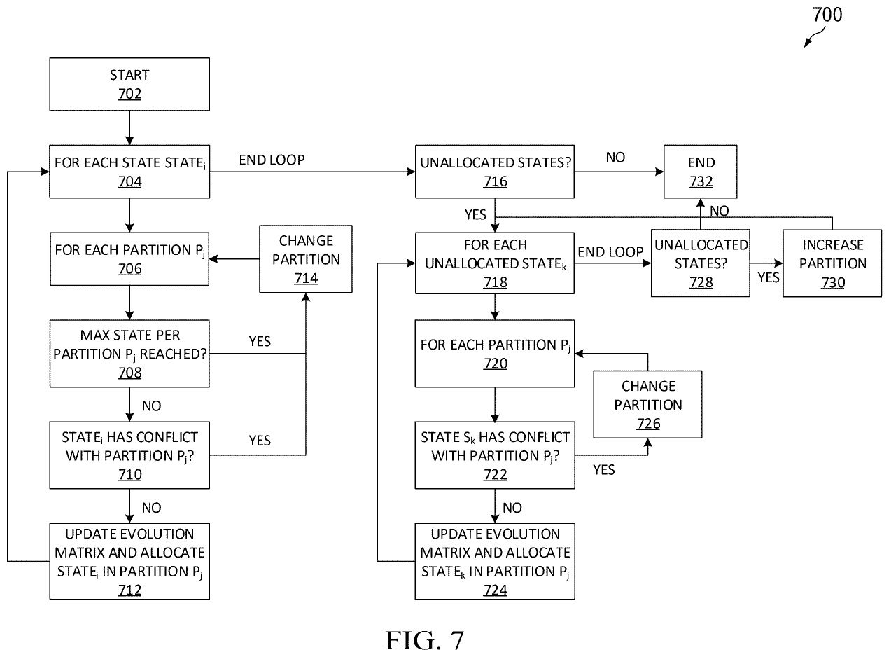

FIG. 7 illustrates a flowchart of an embodiment method 700 for developing an iterative algorithm to optimize the final Design for Test (DFT) architecture and merge output signals of AFSM 206 to be observed using the same output test register. Method 700 begins with a small number of output test registers, the states are partitioned to the criterion previously defined concerning FIG. 4, and if the arrangement is unfeasible, the number of registers are increased until the optimal number of registers have been identified.

The state observation arrangement can be optimized by sharing output test registers between non-adjacent states. Since only one state can be active at any given time, multiple states that cannot transition directly to each other can use the same observation register. For example, if the first state (STATE₁) 102 cannot transition directly to the fifth state (STATE₅) 110 or the fourth state (STATE₄) 108, as in AFSM 100, these three states can share a single observation register. Similarly, if the second state (STATE₂) 104 cannot transition directly to the third state (STATE₃) 106 or the sixth state (STATE₆) 112, as in AFSM 100, these three states can share another observation register. This approach reduces the number of test output registers needed while maintaining the ability to detect all state changes. The observation registers only need to change their values when there is a transition between the states they monitor.

The state observation optimization can be formulated as a partitioning problem with specific constraints. The goal is to organize states into the smallest possible number of groups (partitions), where each partition represents states that can share a single output test register. The partitioning follows a compatibility rule where states that can directly transition to each other (connected states) cannot be placed in the same partition. By minimizing the number of partitions, the number of observation registers required for state monitoring is minimized. The process involves analyzing the state transition relationships and grouping compatible states that cannot directly reach each other, effectively creating an optimal distribution of states across the minimum number of observation registers.

The criterion can be implemented through a bi-dimensional evolution matrix expressing the compatibility between the states (STATEᵢ) and each AFSM arc (Aⱼ). The evolution matrix represents the relationship between arcs in an AFSM state transition diagram and the states that result from the triggering of those transitions. Each column of the matrix corresponds to a specific arc in the AFSM, representing a transition from one state to another. Each row corresponds to a state of the AFSM.

The entries within the matrix indicate the association between a state and an arc. For each cell, a value of ‘1’ signifies that the row's state is the source of the column's arc. A zero or blank entry (‘0’) indicates that the row's state has no relationship with that column's arc. A value of ‘−1’ signifies that the row's state is the destination of the column's arc.

For example, the first and last row of the evolution matrix for the AFSM 100 can be represented in the

$$evolution\_matrix = \{ \begin{matrix}1 & 1 & 0 & 0 & 0 & 0 & 0 & - 1 \\ ⋮ & ⋮ & ⋮ & ⋮ & ⋮ & ⋮ & ⋮ & ⋮ \\ 0 & 0 & 0 & 0 & 0 & - 1 & - 1 & 1\end{matrix} .$$

By examining the first row of the evolution matrix, one can determine that the first state (STATE₁) 102 is the source state for the first arc (A₁) 120, the source state for the second arc (A₂) 122, and the destination state for the eighth arc (A₈) 134. This relationship is captured in the evolution matrix where the first row, corresponding to the first state (STATE₁), includes a value of ‘1’ in the first and second columns, the value ‘−1’ in the eighth column, and a value of ‘0’ in every other column.

Likewise, by examining the last row of the evolution matrix, one can determine that the sixth state (STATE₆) 112 is the source state for the eighth arc (A₈) 134, the destination state for the sixth arc (A₆) 130, and the destination state for the seventh arc (A₇) 132. This relationship is captured in the evolution matrix where the last row, corresponding to the sixth state (STATE₆), includes a value of ‘1’ in the last column, the value ‘−1’ in the sixth and seventh columns, and a value of ‘0’ in every other column.

It should be appreciated that the use of ‘1’, ‘−1’, and ‘0’ values in the evolution matrix represents an example implementation for expressing relationships between states and state transition arcs. In various embodiments, different numerical values, binary representations, or other encoding schemes can be used to represent these relationships, as long as the chosen representation scheme maintains the ability to identify source states, destination states, and non-relationship conditions between states and transitions. The specific values or encoding methods can be selected based on implementation requirements, optimization goals, or tool compatibility considerations while preserving the fundamental relationship identification capabilities needed for the state observation compression analysis.

Method 700 starts at step 702, which is an initialization step. At step 702, the number of partitions is initially set to an initial number. In embodiments, the initial number of partitions is set to two.

Three counter values are initialized to one. The first counter (i) and second counter (k) can range from one to L, the total number of AFSM states. The third counter (j) can range from one to R, the total number of current partitions.

At step 704, each state (STATEᵢ) of the AFSM is evaluated sequentially starting from the initial state, with the first counter (i) tracking the current state being evaluated.

At step 706, for each state (STATEᵢ), each partition (Pⱼ) is evaluated sequentially, with the third counter (j) tracking the current partition being evaluated.

At step 708, a determination is made as to whether the current partition (Pⱼ) has reached its maximum number of allocated states, defined as the total number of AFSM states divided by the current number of partitions. This maximum value is an optimization parameter to help balance the final structure rather than acting as a strict constraint. If this optimization threshold has been reached, the process transitions to step 714 where the next partition is evaluated by incrementing the third counter (j). If the maximum has not been reached, the process continues to step 710.

At step 710, the current state (STATEᵢ) is evaluated for compatibility with states already allocated to the current partition (Pⱼ). Two states can share the same partition if there is no conflict between them in the evolution matrix. A conflict exists if the evolution matrix shows a value of ‘1’ and ‘−1’ in the same column between the current state and any state already in the partition. This indicates a direct transition relationship that would prevent observable state changes if the states shared an observation register.

For a given arc, if the evolution matrix shows a value of ‘1’ for one state and ‘−1’ for another state in the same column, the first state is the source of the arc, and the second state is the destination. If these states were to share an observation output test register, executing this are transition would not produce an observable value change at the observation point, which could lead to fault coverage loss.

At step 712, in response to no conflicts being found at step 710, the cumulative evolution vector for the partition is updated by adding the evolution matrix values of the current state, and the state is allocated to the current partition:

$$cumulative\_evolution \_vector ( {P}_{j} , J ) = {\sum }_{i = 1}^{S} evolution\_matrix ( {STATE}_{i} , J ) ,$$

where S is the number of states in the AFSM. The process then transitions to step 716.

At step 716, a determination is made whether any states remain unallocated. If all states have been allocated, the process ends at step 732. If unallocated states remain, the process continues to step 718 for handling residual states.

At step 718, each unallocated state (STATEₖ) is evaluated sequentially with the second counter (k) tracking the current unallocated state. At step 720, each partition is evaluated sequentially for each unallocated state, regardless of whether it has reached its maximum number of states.

At step 722, the current unallocated state is evaluated for conflicts with states already allocated to the current partition using the same conflict criteria from step 710. At step 724, if no conflicts are found, the cumulative evolution vector for the partition is updated, and the state is allocated to the partition:

$$cumulative\_evolution \_vector ( {P}_{j} , J ) = {\sum }_{k = 1}^{S} evolution\_matrix ( {STATE}_{k} , J ) .$$

Same results can be obtained adding a threshold criterion (e.g., the maximum state per partition at step 708) during the reallocation iteration at step 718.

At step 726, the next partition is evaluated if conflicts are found.

At step 728, if states remain unallocated after evaluating all partitions, the process transitions to step 730 where the number of partitions is increased by one. The process returns to step 718 to attempt allocation with the expanded set of partitions.

If no states remain unallocated at step 728, the process ends at step 732, having successfully allocated all states across the partitions while maintaining the ability to observe all state transitions.

A first aspect relates to a method of implementing a scan collar architecture for testing an asynchronous finite state machine (AFSM), the method comprising receiving a plurality of functional signals corresponding to state transitions in the AFSM; determining compatibility between the functional signals based on source states and destination states of the state transitions; allocating compatible functional signals to shared input test registers of the scan collar architecture, wherein functional signals are compatible in response to their corresponding state transitions having different source states and in response to a destination state of one state transition not being a source state of another state transition; and providing test input signals to the AFSM through the shared input test registers.

In a first implementation form of the method, according to the first aspect as such, the method further comprising generating a conflict matrix representing relationships between the functional signals and state transition arcs of the AFSM, wherein each entry in the conflict matrix indicates whether a functional signal activates or blocks a state transition; and determining a minimum number of shared input test registers based on analyzing the conflict matrix to identify groups of functional signals that can share test registers without violating the compatibility between the functional signals.

In a second implementation form of the method, according to the first aspect as such or any preceding implementation form of the first aspect, generating the conflict matrix comprises assigning a first value to a cell in response to a functional signal triggering a state transition; assigning a second value to the cell in response to a functional signal being blocked for a state transition; and assigning a third value to the cell in response to no relationship existing between a functional signal and a state transition.

In a third implementation form of the method, according to the first aspect as such or any preceding implementation form of the first aspect, a number of the shared input test registers corresponds to a maximum state fanout of the AFSM plus one.

In a fourth implementation form of the method, according to the first aspect as such or any preceding implementation form of the first aspect, the method further comprising determining conflict values for each functional signal based on a number of conflicts with other functional signals; sorting the functional signals based on the conflict values; and allocating functional signals with higher conflict values before allocating functional signals with lower conflict values.

In a fifth implementation form of the method, according to the first aspect as such or any preceding implementation form of the first aspect, the method further comprising redistributing previously allocated functional signals in response to a current functional signal not being allocatable to any existing shared input test register; and adding a new shared input test register in response to the redistribution being unsuccessful.

In a sixth implementation form of the method, according to the first aspect as such or any preceding implementation form of the first aspect, the redistributing comprises identifying conflicting functional signals within the shared input test registers; evaluating whether the conflicting functional signals can be moved to different shared input test registers without creating new conflicts; and reallocating the conflicting functional signals in response to identifying moves that do not create new conflicts.

A second aspect relates to a method of implementing a scan collar architecture for testing an asynchronous finite state machine (AFSM), the method comprising identifying states of the AFSM; generating an evolution matrix representing relationships between the states and state transition arcs of the AFSM; determining compatibility between states based on the evolution matrix, wherein states are compatible in response to having no direct transition relationship between them; allocating compatible states to shared output test registers of the scan collar architecture; and monitoring state transitions through the shared output test registers.

In a first implementation form of the method, according to the second aspect as such, generating the evolution matrix comprises assigning a first value to a cell in response to a state being a source of a state transition; assigning a second value to the cell in response to a state being a destination of a state transition; and assigning a third value to the cell in response to no relationship existing between a state and a state transition.

In a second implementation form of the method, according to the second aspect as such or any preceding implementation form of the second aspect, the method further comprising determining a cumulative evolution vector for each shared output test register based on evolution matrix values of states allocated to that register.

In a third implementation form of the method, according to the second aspect as such or any preceding implementation form of the second aspect, the method further comprising combining state signals from compatible states using logic gates coupled to the shared output test registers.

In a fourth implementation form of the method, according to the second aspect as such or any preceding implementation form of the second aspect, the method further comprising determining an initial target number of shared output test registers; calculating a maximum number of states per shared output test register based on the initial target number; and increasing the target number of shared output test registers in response to states remaining unallocated after attempting allocation.

In a fifth implementation form of the method, according to the second aspect as such or any preceding implementation form of the second aspect, the maximum number of states per shared output test register serves as an optimization parameter for balancing the scan collar architecture rather than as a strict constraint.

In a sixth implementation form of the method, according to the second aspect as such or any preceding implementation form of the second aspect, the monitoring comprises detecting value changes in at least one shared output test register in response to any state transition between states allocated to different shared output test registers.

A third aspect relates to design for test (DFT) architecture for an asynchronous finite state machine (AFSM), comprising a compressed input circuit including a plurality of shared input test registers; a plurality of multiplexers coupled to the shared input test registers; and input routing logic configured to allocate compatible functional signals to shared input test registers in response to corresponding state transitions having different source states and in response to a destination state of one state transition not being a source state of another state transition; a compressed output circuit including a plurality of shared output test registers; a plurality of logic gates coupled to the shared output test registers; and output routing logic configured to allocate compatible state signals to shared output test registers in response to corresponding states having no direct transition relationship; and an AFSM core coupled between the compressed input circuit and the compressed output circuit.

In a first implementation form of the DFT architecture, according to the third aspect as such, the input routing logic allocates the compatible functional signals based on a conflict matrix representing relationships between functional signals and state transition arcs, wherein the conflict matrix is used to determine a minimum number of shared input test registers.

In a second implementation form of the DFT architecture, according to the third aspect as such or any preceding implementation form of the third aspect, the output routing logic allocates the compatible state signals based on an evolution matrix representing relationships between states and state transition arcs, wherein each entry in the evolution matrix indicates whether a state is a source state or destination state for a state transition.

In a third implementation form of the DFT architecture, according to the third aspect as such or any preceding implementation form of the third aspect, the compressed input circuit includes a number of shared input test registers equal to a maximum state fanout of the AFSM plus one, and the compressed output circuit includes a number of shared output test registers determined based on state transition relationships in the AFSM.

In a fourth implementation form of the DFT architecture, according to the third aspect as such or any preceding implementation form of the third aspect, the input routing logic is configured to redistribute previously allocated functional signals in response to a current functional signal not being allocatable to any existing shared input test register, and the output routing logic is configured to increase a number of shared output test registers in response to states remaining unallocated.

In a fifth implementation form of the DFT architecture, according to the third aspect as such or any preceding implementation form of the third aspect, the multiplexers are configured to select between functional mode signals and test mode signals, and the logic gates are configured to combine state signals from states having no direct transition relationship to enable detection of all state transitions.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A method of implementing a scan collar architecture for testing an asynchronous finite state machine (AFSM), the method comprising:
receiving a plurality of functional signals corresponding to state transitions in the AFSM;
determining compatibility between the functional signals based on source states and destination states of the state transitions;
allocating compatible functional signals to shared input test registers of the scan collar architecture, wherein functional signals are compatible in response to their corresponding state transitions having different source states and in response to a destination state of one state transition not being a source state of another state transition; and
providing test input signals to the AFSM through the shared input test registers.

2. The method of claim 1, further comprising:
generating a conflict matrix representing relationships between the functional signals and state transition arcs of the AFSM, wherein each entry in the conflict matrix indicates whether a functional signal activates or blocks a state transition; and
determining a minimum number of shared input test registers based on analyzing the conflict matrix to identify groups of functional signals that can share test registers without violating the compatibility between the functional signals.

3. The method of claim 2, wherein generating the conflict matrix comprises:
assigning a first value to a cell in response to a functional signal triggering a state transition;
assigning a second value to the cell in response to a functional signal being blocked for a state transition; and
assigning a third value to the cell in response to no relationship existing between a functional signal and a state transition.

4. The method of claim 1, wherein a number of the shared input test registers corresponds to a maximum state fanout of the AFSM plus one.

5. The method of claim 1, further comprising:
determining conflict values for each functional signal based on a number of conflicts with other functional signals;
sorting the functional signals based on the conflict values; and
allocating functional signals with higher conflict values before allocating functional signals with lower conflict values.

6. The method of claim 1, further comprising:
redistributing previously allocated functional signals in response to a current functional signal not being allocatable to any existing shared input test register; and
adding a new shared input test register in response to the redistribution being unsuccessful.

7. The method of claim 6, wherein redistributing comprises:
identifying conflicting functional signals within the shared input test registers;
evaluating whether the conflicting functional signals can be moved to different shared input test registers without creating new conflicts; and
reallocating the conflicting functional signals in response to identifying moves that do not create new conflicts.

8. A method of implementing a scan collar architecture for testing an asynchronous finite state machine (AFSM), the method comprising:
identifying states of the AFSM;
generating an evolution matrix representing relationships between the states and state transition arcs of the AFSM;
determining compatibility between states based on the evolution matrix, wherein states are compatible in response to having no direct transition relationship between them;
allocating compatible states to shared output test registers of the scan collar architecture; and
monitoring state transitions through the shared output test registers.

9. The method of claim 8, wherein generating the evolution matrix comprises:
assigning a first value to a cell in response to a state being a source of a state transition;
assigning a second value to the cell in response to a state being a destination of a state transition; and
assigning a third value to the cell in response to no relationship existing between a state and a state transition.

10. The method of claim 8, further comprising determining a cumulative evolution vector for each shared output test register based on evolution matrix values of states allocated to that register.

11. The method of claim 8, further comprising combining state signals from compatible states using logic gates coupled to the shared output test registers.

12. The method of claim 8, further comprising:
determining an initial target number of shared output test registers;
calculating a maximum number of states per shared output test register based on the initial target number; and
increasing the target number of shared output test registers in response to states remaining unallocated after attempting allocation.

13. The method of claim 12, wherein the maximum number of states per shared output test register serves as an optimization parameter for balancing the scan collar architecture rather than as a strict constraint.

14. The method of claim 8, wherein monitoring comprises detecting value changes in at least one shared output test register in response to any state transition between states allocated to different shared output test registers.

15. A design for test (DFT) architecture for an asynchronous finite state machine (AFSM), comprising:
a compressed input circuit including:
a plurality of shared input test registers;
a plurality of multiplexers coupled to the shared input test registers; and
input routing logic configured to allocate compatible functional signals to shared input test registers in response to corresponding state transitions having different source states and in response to a destination state of one state transition not being a source state of another state transition;
a compressed output circuit including:
a plurality of shared output test registers;
a plurality of logic gates coupled to the shared output test registers; and
output routing logic configured to allocate compatible state signals to shared output test registers in response to corresponding states having no direct transition relationship; and
an AFSM core coupled between the compressed input circuit and the compressed output circuit.

16. The DFT architecture of claim 15, wherein the input routing logic allocates the compatible functional signals based on a conflict matrix representing relationships between functional signals and state transition arcs, wherein the conflict matrix is used to determine a minimum number of shared input test registers.

17. The DFT architecture of claim 15, wherein the output routing logic allocates the compatible state signals based on an evolution matrix representing relationships between states and state transition arcs, wherein each entry in the evolution matrix indicates whether a state is a source state or destination state for a state transition.

18. The DFT architecture of claim 15,
wherein the compressed input circuit includes a number of shared input test registers equal to a maximum state fanout of the AFSM plus one, and
wherein the compressed output circuit includes a number of shared output test registers determined based on state transition relationships in the AFSM.

19. The DFT architecture of claim 15,
wherein the input routing logic is configured to redistribute previously allocated functional signals in response to a current functional signal not being allocatable to any existing shared input test register, and
wherein the output routing logic is configured to increase a number of shared output test registers in response to states remaining unallocated.

20. The DFT architecture of claim 15,
wherein the multiplexers are configured to select between functional mode signals and test mode signals, and
wherein the logic gates are configured to combine state signals from states having no direct transition relationship to enable detection of all state transitions.
